(19) United States
(12) Patent Application Publication
(10) Pub. No.: US 2025/0132739 A1
(43) Pub. Date: Apr. 24, 2025

(54) POWER SUPPLY SELECTION SWITCH CIRCUIT AND POWER AMPLIFIER MODULE WITH POWER SUPPLY SELECTION SWITCH CIRCUIT

(71) Applicant: Samsung Electro-Mechanics Co., Ltd., Suwon-si (KR)

(72) Inventors: Shinichi IIZUKA, Suwon-si (KR); Youngwong JANG, Suwon-si (KR); Hyejin LEE, Suwon-si (KR); Jeonghoon KIM, Suwon-si (KR)

(73) Assignee: Samsung Electro-Mechanics Co., Ltd., Suwon-si (KR)

(21) Appl. No.: 18/622,360

(22) Filed: Mar. 29, 2024

(30) Foreign Application Priority Data
Oct. 24, 2023 (KR) 10-2023-0142693

(51) Int. Cl. H03F 3/24; H03K 5/00; H03K 19/20

(52) U.S. Cl. CPC H03F 3/245; H03K 19/20; H03F 2200/451; H03K 5/00; H03K 2005/00078

(57) ABSTRACT

A power selection switch circuit configured to select either one or both of a first power supply voltage and a second power supply voltage, and supply the selected power supply voltage to a power amplifier, the power selection switch circuit includes: an n-type first transistor configured to turn on in response to a first switching control signal having a first voltage generated by charge pumping the first power supply voltage, and supply the first power supply voltage to a power supply terminal of the power amplifier when turned on; and an n-type second transistor configured to turn on in response to a second switching control signal having a second voltage generated by charge pumping the second power supply voltage, and supply the second power supply voltage to the power supply terminal of the power amplifier when turned on.

### CROSS-REFERENCE TO RELATED APPLICATIONS

This application claims the benefit under 35 USC 119 (a) of Korean Patent Application No. 10-2023-0142693 filed on Oct. 24, 2023, in the Korean Intellectual Property Office, the entire disclosure of which is incorporated herein by reference for all purposes.

### BACKGROUND

### 1. Field

This disclosure relates to a power supply selection switch circuit and power amplifier module with power supply selection switch circuit.

### 2. Description of the Background

5th generation cellular communication technology may coexist with 4th-generation LTE technology, requiring different communication methods and corresponding power amplifiers in one communication terminal system.

A typical communication terminal system may use one power management integrated circuit (PMIC) and one power amplifier. To support various communication methods in one communication terminal system, a large number of PMICs may be desired, thus increasing the manufacturing cost of the communication terminal system.

By using a power selection switch, multiple power amplifiers may be driven using a small number of PMICs; thus, the number of power components may be reduced, and the manufacturing cost of the communication terminal may be lowered.

In implementing a power selection switch, if a pair of n-type and p-type transistors is used as a switch core, the size of the p-type transistor may be designed to be large to reduce the on-resistance of the transistor for high DC input voltage. As the size of the p-type transistor increases, when the power selection switch is mounted on a power amplifier module, the area occupied by the p-type transistor may be increased. Accordingly, the size of the power amplifier module and the price may be increased.

The above information is presented as background information only to assist with an understanding of the present disclosure. No determination has been made, and no assertion is made, as to whether any of the above might be applicable as prior art with regard to the disclosure.

### Summary

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a power selection switch circuit is configured to select either one or both of a first power supply voltage and a second power supply voltage, and supply the selected power supply voltage to a power amplifier, the power selection switch circuit includes: an n-type first transistor configured to turn on in response to a first switching control signal having a first voltage generated by charge pumping the first power supply voltage, and supply the first power supply voltage to a power supply terminal of the power amplifier when turned on; and an n-type second transistor configured to turn on in response to a second switching control signal having a second voltage generated by charge pumping the second power supply voltage, and supply the second power supply voltage to the power supply terminal of the power amplifier when turned on.

The power selection switch circuit may further include a switching controller configured to generate the first switching control signal and the second switching control signal using a first bit signal and a second bit signal externally input so that a transistor that is turned on from a turn-off state, among the n-type first transistor and the n-type second transistor, is turned on after being delayed by a predetermined time, and a transistor that is turned off from a turn-on state, among the n-type first transistor and the n-type second transistor, is turned off immediately. The n-type first transistor may be configured to turn off in response to the first switching control signal having a third voltage lower than the first voltage, and the second transistor may be configured to turn off in response to the second switching control signal having a fourth voltage lower than the second voltage.

The switching controller may include a logic circuit configured to generate a first logic signal for generating the first switching control signal and a second logic signal for generating the second switching control signal by combining the first bit signal and the second bit signal; a first delay circuit configured to delay the first logic signal to generate a first delay signal; a second delay circuit configured to delay the second logic signal to generate a second delay signal; a first buffer control circuit configured to supply the first voltage or the third voltage as the first switching control signal to a control terminal of the n-type first transistor in response to the first delay signal; and a second buffer control circuit configured to supply the second voltage or the fourth voltage as the second switching control signal to a control terminal of the n-type second transistor in response to the second delay signal.

The first bit signal and the second bit signal may have a value of 0 or 1. The logic circuit may be configured to set both the first logic signal and the second logic signal to a low level so that when the first bit signal and the second bit signal are both 1 or both 0, both the n-type first transistor and the n-type second transistor are turned off.

The switching controller may further include a first clock generator configured to operate in response to the first logic signal, and generate a first clock signal having a fifth voltage and a sixth voltage lower than the fifth voltage; a second clock generator configured to operate in response to the second logic signal, and generate a second clock signal having the fifth voltage and the sixth voltage; a first charge pump circuit configured to generate the first voltage by charge pimping the first power supply voltage by the fifth voltage in response to the first clock signal, and provide the first voltage to the first buffer control circuit; and a second charge pump circuit configured to generate the second voltage by charge pimping the second power supply voltage by the fifth voltage in response to the second clock signal, and provide the second voltage to the second buffer control circuit.

The first logic signal and the second logic signal may have a high level and a low level. The first clock generator and the second clock generator may operate at the high level of the first logic signal and the high level of the second logic signal, and do not operate at the low level.

The logic circuit may include a NAND gate configured to receive the first bit signal and the second bit signal; a first AND gate configured to receive the first bit signal and an output of the NAND gate, and output the first logic signal; and a second AND gate configured to receive the second bit signal and an output of the NAND gate, and output the second logic signal.

The first delay circuit may include a first delay cell configured to delay the first logic signal; and a first AND gate configured to receive the first logic signal and a signal delayed by the first delay cell. The second delay circuit may include a second delay cell configured to delay the second logic signal; and a second AND gate configured to receive the second logic signal and a signal delayed by the second delay cell.

In another general aspect, a power amplifier module includes a power amplifier configured to receive a power supply voltage from a power supply terminal, and amplify an input signal and output the amplified signal; and a power selection switch circuit configured to provide either one or both power supply voltage of a first power supply voltage supplied from a first power integrated circuit (IC) and a second power supply voltage supplied from a second power IC to the power supply terminal. The power selection switch circuit may include an n-type first transistor configured to have a first terminal connected to the first power IC, a second terminal connected to the power supply terminal, and a control terminal receiving a first switching control signal having a first voltage generated by charge pumping the first power supply voltage; and an n-type second transistor configured to have a first terminal connected to the second power IC, a second terminal connected to the power supply terminal, and a control terminal receiving a second switching control signal having a second voltage generated by charge pumping the second power supply voltage.

The power selection switch circuit may further include a switching controller configured to generate the first switching control signal and the second switching control signal so that the n-type first transistor and the n-type second transistor are turned on after being delayed by a predetermined time when the n-type first transistor and the n-type second transistor change from the turn-off state to the turn-on state.

The n-type first transistor may be configured to turn off in response to the first switching control signal having a third voltage lower than the first voltage, and the n-type second transistor may be configured to turn off in response to the second switching control signal having a fourth voltage lower than the second voltage.

The switching controller may include a logic circuit configured to generate a first logic signal for generating the first switching control signal and a second logic signal for generating the second switching control signal by combining a first bit signal and a second bit signal input from an outside; a first delay circuit configured to delay the first logic signal to generate a first delay signal; a second delay circuit configured to delay the second logic signal to generate a second delay signal; a first buffer control circuit configured to supply the first voltage or the third voltage as the first switching control signal to a control terminal of the n-type first transistor in response to the first delay signal; and a second buffer control circuit configured to supply the second voltage or the fourth voltage as the second switching control signal to a control terminal of the n-type second transistor in response to the second delay signal.

The first bit signal and the second bit signal may have a value of 0 or 1, and the logic circuit may be configured to set both the first logic signal and the second logic signal to a low level so that when the first bit signal and the second bit signal are both 1 or both 0, both the n-type first transistor and the n-type second transistor are turned off.

The switching controller may include a first clock generator configured to operate in response to the first logic signal and generate a first clock signal having a fifth voltage and a sixth voltage lower than the fifth voltage; a second clock generator configured to operate in response to the second logic signal and generate a second clock signal having the fifth voltage and the sixth voltage; a first charge pump circuit configured to generate the first voltage by charge pimping the first power supply voltage by the fifth voltage in response to the first clock signal, and provide the first voltage to the first buffer control circuit; and a second charge pump circuit configured to generate the second voltage by charge pimping the second power supply voltage by the fifth voltage in response to the second clock signal, and provide the second voltage to the second buffer control circuit.

The n-type first transistor may include a plurality of third transistors connected in parallel, the n-type second transistor may include a plurality of fourth transistors connected in parallel, and the plurality of third transistor and the plurality of fourth transistor may be n-type transistors.

Other features and aspects will be apparent from the following detailed description, the drawings, and the claims.

### BRIEF DESCRIPTION OF THE DRAWINGS

FIG. 1 is a diagram schematically showing a power selection switch circuit according to one embodiment.

FIG. 2 is a diagram showing the power selection switch circuit 100 shown in FIG. 1.

FIG. 3 is a diagram showing the switching controller 110 shown in FIG. 2.

FIG. 4 is a diagram illustrating a logic circuit 111 according to one embodiment.

FIG. 5 is a diagram showing a logic table of the logic circuit shown in FIG. 4.

FIG. 6 is a diagram showing the first delay circuit 112 shown in FIG. 4.

FIG. 7 is a diagram showing the second delay circuit 113 shown in FIG. 4.

FIG. 8 is a diagram showing the relationship between an input signal and an output signal of the delay circuit shown in FIG. 6.

FIG. 9 is a diagram showing the operation timing of a power selection switch circuit according to one embodiment.

FIG. 10 is a diagram showing detailed blocks of a switching controller according to one embodiment.

FIG. 11 is a diagram illustrating an example of the charge pump circuit 125 shown in FIG. 10.

FIG. 12 is a diagram showing the operating state of the charge pump circuit 125 in the first operation section.

FIG. 13 is a diagram showing the operating state of the charge pump circuit 125 in the second operation section.

FIG. 14 is a diagram illustrating an example of a communication terminal system to which the power selection switch circuit shown in FIG. 1 is applied.

FIG. 15 is a diagram showing another example of a communication terminal system to which the power selection switch circuit shown in FIG. 1 is applied.

Throughout the drawings and the detailed description, unless otherwise described, the same reference numerals refer to the same elements. The drawings may not be to scale, and the relative size, proportions, and depiction of elements in the drawings may be exaggerated for clarity, illustration, and convenience.

### DETAILED DESCRIPTION

Hereinafter, while examples of the present disclosure will be described in detail with reference to the accompanying drawings, it is noted that examples are not limited to the same.

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of this disclosure. For example, the sequences of operations described herein are merely examples, and are not limited to those set forth herein, but may be changed as will be apparent after an understanding of this disclosure, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of this disclosure.

Throughout the specification, when an element, such as a layer, region, or substrate is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items; likewise, “at least one of” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms, such as “above,” “upper,” “below,” “lower,” and the like, may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above,” or “upper” relative to another element would then be “below,” or “lower” relative to the other element. Thus, the term “above” encompasses both the above and below orientations depending on the spatial orientation of the device. The device may also be oriented in other ways (rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

Herein, it is noted that use of the term “may” with respect to an example, for example, as to what an example may include or implement, means that at least one example exists in which such a feature is included or implemented while all examples are not limited thereto.

The features of the examples described herein may be combined in various ways as will be apparent after an understanding of this disclosure. Further, although the examples described herein have a variety of configurations, other configurations are possible as will be apparent after an understanding of this disclosure.

Throughout the specification, an RF signal includes Wi-Fi (IEEE 802.11 family, etc.), WiMAX (IEEE 802.16 family, etc.), IEEE 802.20, long term evolution (LTE), Evolution-Data Optimized (Ev-DO), high-speed packet access plus (HSPA+), high-speed downlink packet access plus (HSDPA+), high-speed uplink packet access plus (HSUPA+), Enhanced Data GSM Evolution (EDGE), Global System for Mobile communication (GSM), Global Positioning System (GPS), General Packet Radio Service (GPRS), Code Division Multiple Access (CDMA), Time Division Multiple Access (TDMA), digital enhanced cordless communication (DECT), Bluetooth, third generation (3G), fourth generation (4G), fifth generation (5G), and any other wireless and wired protocols designated thereafter, but is not limited thereto.

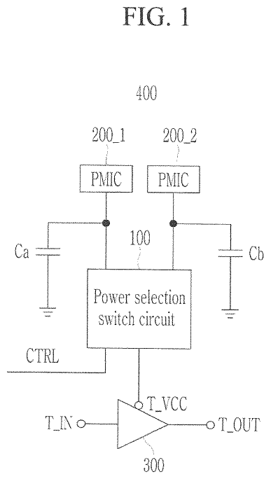

FIG. 1 is a diagram schematically showing a power selection switch circuit according to one embodiment.

Referring to FIG. 1, a power selection switch circuit 100 may receive a power voltage VCC1 from a Power Management Integrated Circuit (PMIC) 200_1, receive a power voltage VCC2 from the PMIC 200_2, select one of the power supply voltages VCC1 and VCC2 based on the input control signal CTRL, and output the selected power supply voltage to the power terminal T_VCC of a power amplifier 300.

The PMIC 200_1 may generate the power supply voltage VCC1 from the main power supply.

The PMIC 200_2 may generate the power supply voltage VCC2 from the main power supply.

The capacitor Ca may be connected between the PMIC 200_1 and ground, filter noise of the power supply voltage VCC1 input from the PMIC 200_1, and stabilize the power supply voltage VCC1.

The capacitor Cb may be connected between the PMIC 200_2 and ground, filter the power supply voltage VCC2 input from the PMIC 200_2, and stabilize the power supply voltage VCC2.

The power amplifier 300 may include an input terminal T_IN, an output terminal T_OUT, and a power terminal T_VCC. The power amplifier 300 may operate by receiving the power supply voltage selected by the power selection switch circuit 100 through the power terminal T_VCC, amplify an RF signal input to the input terminal T_IN, and output the amplified RF signal to the terminal T_OUT.

The power selection switch circuit 100 and the power amplifier 300 may be integrated and implemented as a single power amplifier module 400.

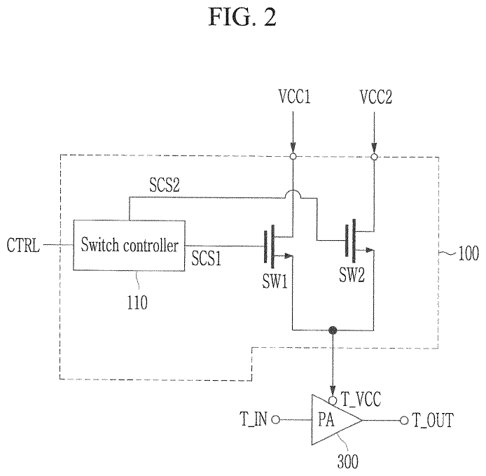

FIG. 2 is a diagram showing the power selection switch circuit 100 shown in FIG. 1.

Referring to FIG. 2, the power selection switch circuit 100 may include a transistor SW1, a transistor SW2, and a switch controller 110.

The transistor SW1 may be connected between the PMIC 200_1 and the power terminal T_VCC of the power amplifier 300. The transistor SW1 may supply the power supply voltage VCC1 to the power terminal T_VCC of the power amplifier 300 by turning on according to the first switching control signal SCS1 of the switch controller 110 input through the gate.

The transistor SW2 may be connected between the PMIC 200_2 and the power terminal T_VCC of the power amplifier 300. The transistor SW2 may supply the power supply voltage VCC2 to the power terminal T_VCC of the power amplifier 300 by turning on according to the second switching control signal SCS2 of the switch controller 110 input through the gate.

According to an embodiment, the transistors SW1 and SW2 may be n-type transistors. The transistor SW1 may be implemented as a single n-type transistor or by connecting multiple n-type transistors in parallel. The transistor SW2 may also be implemented as a single n-type transistor, or may be implemented by connecting multiple n-type transistors in parallel.

Meanwhile, unlike the embodiment, the transistor SW1 and the transistor SW2 may be implemented by connecting at least one n-type transistor and at least one p-type transistor in parallel. The on-resistance of the transistors SW1 and SW2 may be reduced by setting the chip size of the transistors SW1 and SW2 to be large. When the transistors SW1 and SW2 may be implemented by connecting at least one n-type transistor and at least one p-type transistor in parallel, the chip size of the p-type transistors of the transistors SW1 and SW2 may be increased in order to reduce the on-resistance of the transistors SW1 and SW2 for high input voltage, so the overall size of the transistors SW1 and SW2 may be increased, respectively. For this reason, when the power selection switch circuit 100 is configured using the transistors SW1 and SW2 implemented by connecting at least one n-type transistor and at least one p-type transistor in parallel, the mounting area of the transistors SW1 and SW2 within the power amplifier module 400 may be increased.

However, if the power selection switch circuit 100 is configured with a transistor SW1 composed of only n-type transistors and a transistor SW2 composed of only n-type transistors as in the embodiment, since a p-type transistor, which requires a larger chip size, is not used, the mounting area of the transistor SW1 and transistor SW2 within the power amplifier module 400 may be reduced.

The switch controller 110 may receive a control signal CTRL from the outside and generate a first switching control signal SCS1 that controls the transistor SW1 and a second switching control signal SCS2 that controls the transistor SW2 in response to the control signal CTRL. The switch controller 110 may output a first switching control signal SCS1 to the gate of the transistor SW1 and output a second switching control signal SCS2 to the gate of the transistor SW2.

The control signal CTRL may have a 2-bit value. 1 bit of the 2 bits may be used to generate the first switching control signal SCS1, and the remaining 1 bit of the 2 bits may be used to generate the second switching control signal SCS2.

When the first switching control signal SCS1 is an on-control signal and the second switching control signal SCS2 is an off-control signal, the transistor SW1 may be turned on, and the transistor SW2 may be turned off. Accordingly, the power voltage VCC1 may be applied to the power terminal T_VCC of the power amplifier 300 through the transistor SW1.

When the first switching control signal SCS1 is an off-control signal and the second switching control signal SCS2 is an on-control signal, the transistor SW1 may be turned off, and the transistor SW2 may be turned on. Accordingly, the power supply voltage VCC2 may be applied to the power terminal T_VCC of the power amplifier 300 through the transistor SW2.

The switching control signals SCS1 and SCS2 may have a high-level voltage and a low-level voltage, respectively. Since the transistors SW1 and SW2 are n-type transistors, the on-control signal may be a high-level voltage and the off-control signal may be a low-level voltage.

The switch controller 110 may generate a voltage higher than the input voltage to reduce the on-resistance of the n-type transistor SW1 of the n-type transistor SW2, and use the generated voltage as the high-level voltage of the first switching control signal SCS1 and the high-level voltage of the second switching control signal SCS2.

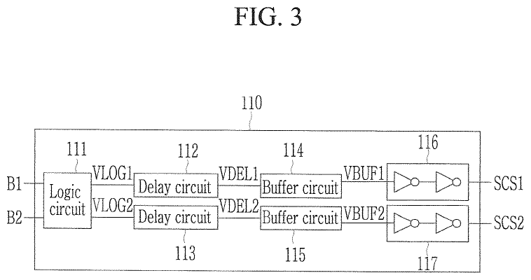

FIG. 3 is a diagram showing the switching controller 110 shown in FIG. 2.

Referring to FIG. 3, the switching controller 110 may include a logic circuit 111, a first delay circuit 112, a second delay circuit 113, a first buffer circuit 114, a second buffer circuit 115, a first buffer gate 116, and a second buffer gate 117.

The first delay circuit 112, the first buffer circuit 114, and the first buffer gate 116 may operate to generate the first switching control signal SCS1 for controlling the transistor SW1.

The second delay circuit 113, second buffer circuit 115, and second buffer gate 117 may operate to generate the second switching control signal SCS2 for controlling the transistor SW2.

The logic circuit 111 may receive bit signals B1 and B2 as external control signals, and may generate and output logic signals VLOG1 and VLOG2 in response to the bit signals B1 and B2. The bit signal B1 and the logic signal VLOG1 may be used to control the transistor SW1, and the bit signal B2 and the logic signal VLOG2 may be used to control the transistor SW2. The bit signal B1 may correspond to 1 bit of the 2 bits of the control signal CTRL, and the bit signal B2 may correspond to the remaining 1 bit of the 2 bits of the control signal CTRL.

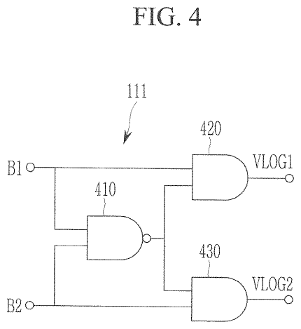

FIG. 4 is a diagram illustrating a logic circuit 111 according to one embodiment.

As shown in FIG. 4, the logic circuit 111 may include a negative-AND (NAND) gate 410, an AND gate 420, and an AND gate 430.

The NAND gate 410 may receive the bit signal B1 and the bit signal B2, perform a negated AND operation on the bit signal B1 and the bit signal B2, and output it to the AND gate 420 and the AND gate 430.

The AND gate 420 may receive the bit signal B1 and the output signal of the NAND gate 410, generate a logic signal VLOG1 by logically multiplying the bit signal B1 and the output signal of the NAND gate 410, and output the logic signal VLOG1.

The AND gate 430 may receive the bit signal B2 and the output signal of the NAND gate 410, generate a logic signal VLOG2 by logically multiplying the bit signal B2 and the output signal of the NAND gate 410, and output the logic signal VLOG2.

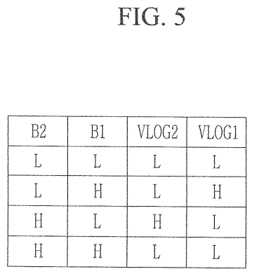

FIG. 5 is a diagram showing a logic table of the logic circuit shown in FIG. 4.

Referring to FIG. 5, the logic circuit 111 may have four states corresponding to the bit signals B1 and B2.

If the bit signals B1 and B2 are both low level L, both the logic signals VLOG1 and VLOG2 may have a low level L. If the bit signals B1 and B2 are both high level H, both the logic signals VLOG1 and VLOG2 may have low level L. If the bit signal B1 is a low level L and the bit signal B2 is a high level H, the logic signal VLOG1 may have a low level L and the logic signal VLOG2 may have a high level H. If the bit signal B1 is high level H and the bit signal B2 is low level L, the logic signal VLOG1 may have a high level H and the logic signal VLOG2 may have a low level L.

When the logic signal VLOG1 is at a high level H, the transistor SW1 may be turned on. When the logic signal VLOG1 is at a low level L, the transistor SW1 may be turned off.

When the logic signal VLOG2 is at a high level H, the transistor SW2 may be turned on. When the logic signal VLOG2 is at a low level L, the transistor SW2 may be turned off.

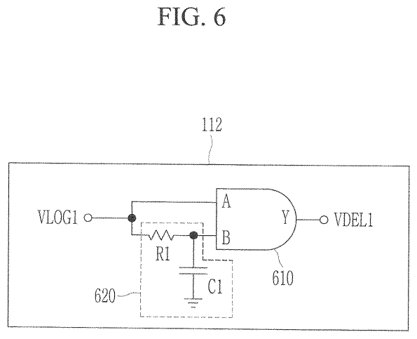

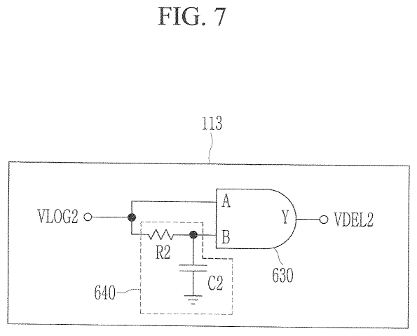

FIG. 6 is a diagram showing the first delay circuit 112 shown in FIG. 4, and FIG. 7 is a diagram showing the second delay circuit 113 shown in FIG. 4.

Referring to FIG. 6, the first delay circuit 112 may include an AND gate 610 and a delay cell 620.

The AND gate 610 and the delay cell 620 may generate a delay signal VDEL1 by delaying the logic signal VLOG1. The delay cell 620 may include a resistor R1 and a capacitor C1.

The logic signal VLOG1 may be input to the input terminal A of the AND gate 610. The capacitor C1 may be connected between the input terminal B of the AND gate 610 and ground. The logic signal VLOG1 may be input to one end of the resistor R1, and the other end of the resistor R1 may be connected to the input terminal B of the AND gate 610. Here, the delay cell 620 may delay the logic signal VLOG1 by a predetermined time and then output it to the input terminal B of the AND gate 610. The RC time constant value may be determined by the value of the resistor R1 and the value of the capacitor C1, and the logic signal VLOG1 may be delayed by this RC time constant value. Meanwhile, the delay cell 620 is an element that delays a signal and may be implemented using other methods, such as the resistor R1 and the capacitor C1. The AND gate 610 may generate a signal VDEL1 by logically multiplying signals input to the input terminal A and the input terminal B, and output the signal VDEL1.

Referring to FIG. 7, the second delay circuit 113 may include an AND gate 630 and a delay cell 640.

The AND gate 630 and the delay cell 640 may generate a delay signal VDEL2 by delaying the logic signal VLOG1. The delay cell 640 may include a resistor R2 and a capacitor C2.

The logic signal VLOG2 may be input to the input terminal A of the AND gate 630. The capacitor C2 may be connected between the input terminal B of the AND gate 630 and ground. The logic signal VLOG2 may be input to one end of the resistor R2, and the other end of the resistor R2 may be connected to the input terminal B of the AND gate 630. Here, the delay cell 640 may delay the logic signal VLOG2 by a predetermined time and then output it to the input terminal B of the AND gate 630. The RC time constant value may be determined by the value of the resistor R2 and the capacitor C2, and the logic signal VLOG2 may be delayed by this RC time constant value. Meanwhile, the delay cell 640 is an element that delays a signal and can be implemented using a resistor R2 and a capacitor C2, as well as other methods. The AND gate 630 may generate a signal VDEL2 by logically multiplying signals input to the input terminal A and the input terminal B, and output the signal VDEL2.

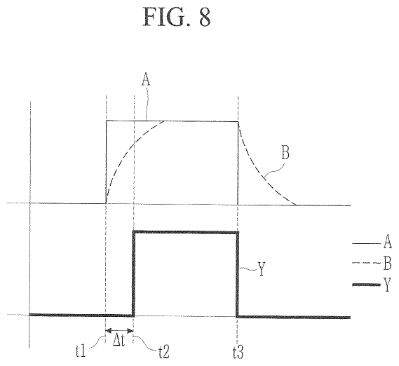

FIG. 8 is a diagram showing the relationship between an input signal and an output signal of the delay circuit shown in FIG. 6. In FIG. 8, the description is based on the AND gate 610 and the delay cell 620, but the AND gate 630 and the delay cell 640, shown in FIG. 7, can also be applied equally.

Referring to FIG. 8, at time t1, the logic signal VLOG1 may change from low level to high level.

At time t1, the signal input to the input terminal A may be changed immediately from low level to high level, but the signal input to the input terminal B may be delayed by a predetermined time Δt by the delay cell 620 and then may be changed from low level to high level. The signal output to the output terminal Y of the AND gate 610 may be changed from low level to high level at time t2 in which both the signal input to the input terminal A and the signal input to the input terminal B become high level due to the operation characteristics of the AND gate 610 after a predetermined delay time Δt. Accordingly, when the transistor SW1 changes from the off state to the on state, the turn-off of the transistor SW1 may be delayed by a predetermined delay time Δt.

Meanwhile, at time t3, the logic signal VLOG1 may change from high level to low level.

At time t3, the signal input to the input terminal A may be changed immediately from high level to low level, but the signal input to the input terminal B may be delayed by a predetermined time by the delay cell 620 and then may be changed from high level to low level. Due to the operation characteristics of the AND gate, the signal output to the output terminal Y of the AND gate 610 may be immediately changed from high level to low level without delay time.

In other words, the first delay circuit 112 may generate a delay in the output signal VDEL1 only when the logic signal VLOG1 changes from a low level to a high level, and may not generate a delay in the output signal VDEL1 when the logic signal VLOG1 changes from a high level to a low level. When the logic signal VLOG1 changes from a low level to a high level, the transistor SW1 may be changed from a turn-off state to a turn-on state, and the transistor SW1 may be turned on after being delayed by a predetermined time. When the logic signal VLOG1 changes from high level to low level, the transistor SW1 may be changed from the turn-on state to the turn-off state, and the transistor SW1 may be turned off immediately without delay time.

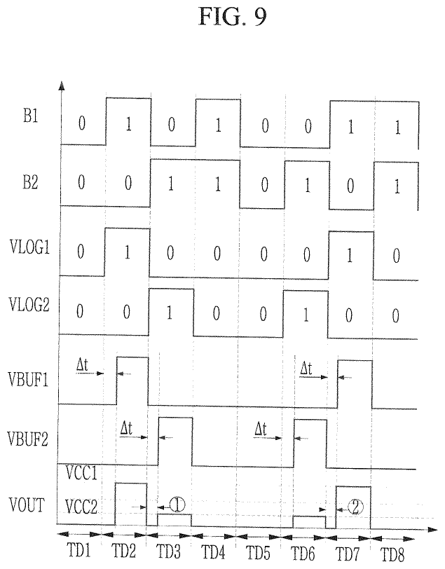

By these delay circuits 112 and 113, simultaneous turn-on of the transistors SW1 and SW2 may be prevented, which will be further explained in detail with reference to FIG. 9.

Again, referring to FIG. 3, the first buffer circuit 114 may receive the delay signal VDEL1 output from the first delay circuit 112 and output the buffer signal VBUF1. The first buffer circuit 114 may convert the delay signal VDEL1 into the buffer signal VBUF1. Since the delay signal VDEL1 output from the first delay circuit 112 is a logic signal with a low current level, the first buffer circuit 114 may convert the delay signal VDEL1 output from the first delay circuit 112 into a buffer signal VBUF1 with a high current level.

The second buffer circuit 115 may receive the delay signal VDEL2 output from the second delay circuit 113 and output the buffer signal VBUF2. The second buffer circuit 115 may convert the delay signal VDEL2 into the buffer signal VBUF2.

Since the specific configuration and operation of the first buffer circuit 114 and the second buffer circuit 115 may be known to those skilled in the art, a further detailed description of the buffer circuits 114 and 115 will be omitted.

The first buffer gate 116 may receive the buffer signal VBUF1 and output a first switching control signal SCS1. The first buffer gate 116 may include an even number of inverter gates connected in series. Since the first buffer gate 116 has a structure in which an even number of inverters are connected in series, the first buffer gate 116 may output the buffer signal VBUF1 as is, and the first switching control signal SCS1 may be the buffer signal VBUF2.

The second buffer gate 117 may receive the buffer signal VBUF2 and output a second switching control signal SCS2. The second buffer gate 117 may include an even number of inverter gates connected in series. Since the second buffer gate 117 has a structure in which an even number of inverters are connected in series, the second buffer gate 117 may output the buffer signal VBUF2 as is, and the second switching control signal SCS2 may be the buffer signal VBUF2.

These buffer gates 116 and 117 may set the voltage levels of the input terminal and the output terminal to be the same.

FIG. 9 is a diagram showing the operation timing of a power selection switch circuit according to one embodiment. FIG. 9 shows the logic signals VLOG1 and VLOG2, the buffer signals VBUF1 and VBUF2, and the power supply terminal voltage VOUT according to the bit signals B1 and B2.

Referring to FIG. 9, when the bit signal B1 and the bit signal B2 are input, the logic circuit 111 may output the logic signals VLOG1 and VLOG2 according to the bit values of the bit signals B1 and B2.

In period TD1, the logic signal VLOG1 is at a low level, and the logic signal VLOG2 is also at a low level. In this case, both the buffer signals VBUF1 and VBUF2 are low voltage, and both the transistors SW1 and SW2 are in the off state. Accordingly, none of the power supply voltages VCC1 and VCC2 are output.

In period TD2, the logic signal VLOG1 is at a high level, and the logic signal VLOG2 is at a low level. In this case, the buffer signal VBUF1 is a high voltage, and the buffer signal VBUF2 is a low voltage. Considering the periods TD1 and TD2 together, the logic signal VLOG1 may be changed from the low level to the high level. As explained in FIGS. 7 and 8, the second delay circuit 113 generates a delay in the output signal when the logic signal changes from the low level to the high level (changes from 0 to 1). Accordingly, since the buffer signal VBUF1 changes from a low voltage to a high voltage after a predetermined delay time Δt, the turn-on of the transistor SW1 may be delayed. That is, the transistor SW1 may not be turned on immediately when the logic signal VLOG1 changes from the low level to the high level, but may be turned on after a delay time Δt. The transistor SW2 may remain turned off. Accordingly, the power selection switch circuit 100 may output the power supply voltage VCC1, and the power supply terminal voltage VOUT may be the power supply voltage VCC1.

In period TD3, the logic signal VLOG1 is at a low level, and the logic signal VLOG2 is at a high level. Considering the periods TD2 and TD3 together, the logic signal VLOG1 changes from a high level to a low level, and the logic signal VLOG2 changes from a low level to a high level. As explained in FIGS. 7 and 8, the second delay circuit 113 may generate a delay in the output signal when the logic signal VLOG2 changes from a low level to a high level (changes from 0 to 1). Accordingly, since the buffer signal VBUF2 changes from the low voltage to the high voltage after a predetermined delay time Δt, the turn-on of the transistor SW2 may be delayed. Meanwhile, in the period TD3, the buffer signal VBUF1 changes from the high voltage to the low voltage immediately without delay time, so the transistor SW1 may be immediately turned off. That is, in the period TD3, an overlap off period (\textcircled{1}) may occur in which both the transistor SW1 and the transistor SW2 are turned off.

A case may occur where the transistor SW1 and transistor SW2 are turned on simultaneously in a period when the levels of the logic signals VLOG1 and VLOG2 change. When the transistors SW1 and SW2 are turned on at the same time, current paths may be formed along the transistors SW1 and SW2 in the PMICs 200a and 200b, and accordingly, overcurrent may be generated. According to the embodiment, by delaying the turn-on of the transistor SW2 through the second delay circuit 113, the overlap off period (\textcircled{1}) of the transistors SW1 and SW2 may be set, so the transistors SW1 and SW2 may be prevented from turning on at the same time.

Accordingly, in the period TD3, the transistor SW1 may be immediately turned off and the transistor SW2 may be turned on after a predetermined delay time Δt, the power selection switch circuit 100 may output the power supply voltage VCC2, and the power supply terminal voltage VOUT may be the power supply voltage VCC2.

In period TD4, the logic signal VLOG1 is at a high level and the logic signal VLOG2 is also at a high level. Considering the periods TD3 and TD4 together, the logic signal VLOG2 may be changed from the high level to the low level. When the logic signal VLOG2 changes from the high level to the low level, the buffer signal VBUF2 may be immediately changed from the high voltage to the low voltage without delay time, so the transistor SW2 may be turned off immediately. The transistor SW1 may remain turned off. Accordingly, in the period TD4, the power selection switch circuit 100 does not output any of the power supply voltage VCC1 and the power supply voltage VCC2.

In period TD5, the logic signal VLOG1 is at a low level, and the logic signal VLOG2 is also at a low level. Considering the periods TD4 and TD5 together, the logic signals VLOG1 and VLOG2 both maintain a low level, so the buffer signals VBUF1 and VBUF2 may also maintain low voltage. Accordingly, in the period TD5, the power selection switch circuit 100 does not output any of the power supply voltage VCC1 and the power supply voltage VCC2.

In period TD6, the logic signal VLOG1 is at a low level, and the logic signal VLOG2 is at a high level. Considering the periods TD5 and TD6 together, the logic signal VLOG2 may be changed from the low level to the high level. As explained in FIGS. 7 and 8, the second delay circuit 113 may generate a delay in the output signal when the logic signal VLOG2 changes from the low level to the high level. Accordingly, since the buffer signal VBUF2 changes from the low voltage to the high voltage after a predetermined delay time Δt, the turn-on of the transistor SW2 may be delayed. Meanwhile, in the period TD6, the buffer signal VBUF1 maintains the low voltage, so the transistor SW1 may remain turned off. Accordingly, in the period TD6, the transistor SW2 may be turned on after a predetermined delay time Δt, the power selection switch circuit 100 may output the power supply voltage VCC2, and the power supply terminal voltage VOUT may be power supply voltage VCC2.

In period TD7, the logic signal VLOG1 is at a high level, and the logic signal VLOG2 is at a low level. Considering the periods TD6 and TD7 together, the logic signal VLOG1 may be changed from the low level to the high level and the logic signal VLOG2 may be changed from the high level to the low level. As described in FIGS. 7 and 8, the second delay circuit 113 may generate a delay in the output signal when the logic signal VLOG1 changes from the low level to the high level. Accordingly, since the buffer signal VBUF1 changes from a low voltage to a high voltage after a predetermined delay time Δt, the turn-on of the transistor SW1 may be delayed. Meanwhile, in the period TD7, the buffer signal VBUF2 immediately changes from the high voltage to the low voltage without delay time, so the transistor SW2 may be immediately turned off. That is, in the period TD7, when the logic signal VLOG1 changes from the low level to the high level and the logic signal VLOG2 changes from the high level to the low level, an overlap off period (\textcircled{2}) may occur in which both the transistor SW1 and the transistor SW2 are turned off, and so the transistors SW1 and SW2 may be prevented from turning on at the same time due to the overlap off period (\textcircled{2}).

Accordingly, in the period TD7, the transistor SW2 may be immediately turned off and the transistor SW1 may be turned on after a predetermined delay time Δt. The power selection switch circuit 100 may output the power supply voltage VCC1, and the power supply terminal voltage VOUT may be the power supply voltage VCC1.

In period TD8, the logic signal VLOG1 is at a low level and the logic signal VLOG2 is at a low level. Considering the periods TD7 and TD8 together, the logic signal VLOG1 may be changed from the high level to the low level. When the logic signal VLOG1 changes from the high level to the low level, the buffer signal VBUF1 may be immediately changed from a high voltage to a low voltage without delay time, so the transistor SW1 may be turned off immediately. The transistor SW2 may remain turned off. Accordingly, in the period TD8, the power selection switch circuit 100 does not output any of the power supply voltage VCC1 and the power supply voltage VCC2.

As such, the power selection switch circuit 100, according to the embodiment, may change the low voltage to the high voltage after a predetermined delay time when any one of the buffer signal VBUF1 and the buffer signal VBUF2 changes from the low voltage to the high voltage. Therefore, when the voltage levels of the buffer signal VBUF1 and VBUF2 change, the transistor SW1 and the transistor SW2 may be prevented from turning on at the same time, and the power amplifier 300 may be protected from overcurrent.

In addition, when the bit signal B1 and the bit signal B2 input from the outside are at a low level or a high level at the same time, for example, in the period TD1, the period TD4, or the period TD8, the power selection switch circuit 100 according to the embodiment may turn off the transistor SW1 and the transistor SW2 at the same time, so it is possible to prevent the transistor SW1 and the transistor SW2 from being turned on at the same time, and to protect the power amplifier 300 from overcurrent.

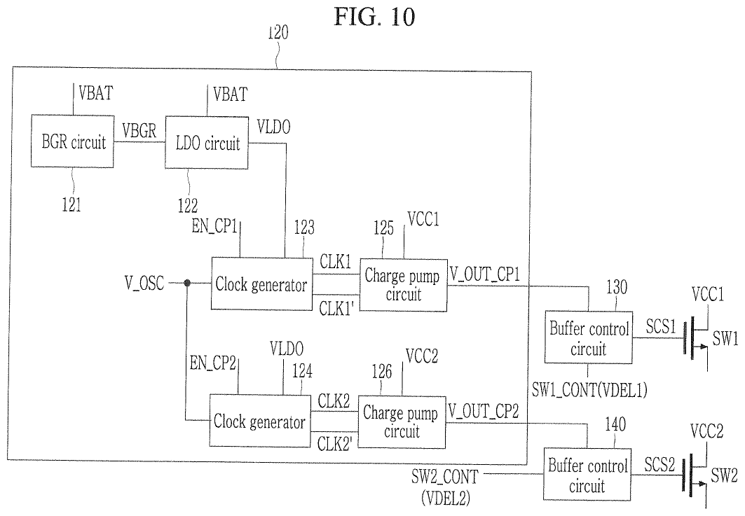

FIG. 10 is a diagram showing detailed blocks of a switching controller according to one embodiment.

Referring to FIG. 10, the switching controller 110 may further include a control voltage generator 120.

In FIG. 10, the first buffer circuit 114 and the first buffer gate 116 of FIG. 3 are shown integrated into the buffer control circuit 130. The second buffer circuit 115 and second buffer gate 117 of FIG. 3 are shown integrated into the buffer control circuit 140, and the logic circuit 111, first delay circuit 112, and second delay circuit 113 are omitted.

As explained previously, both the transistors SW1 and SW2 are n-type transistors, so in order to reduce the on-resistance of the transistors SW1 and SW2 against high input voltage, transistors SW1 and SW2 must be controlled with a voltage higher than the input power voltage VCC1 or VCC2.

The control voltage generator 120 may generate a voltage higher than the power supply voltage VCC1 or VCC2, and this voltage may be used to control the transistors SW1 and SW2.

The control voltage generator 120 may include a band gap reference (BGR) circuit 121, a low dropout (LDO) circuit 122, a clock generator 123, a clock generator 124, a charge pump circuit 125, and a charge pump circuit 126.

The BGR circuit 121 may generate a reference voltage VBGR from the battery voltage VBAT supplied from the battery power source. The BGR circuit 121 may generate the reference voltage VBGR, whose voltage level does not change depending on temperature and external environment.

The LDO circuit 122 may generate a positive voltage VLDO lower than the battery voltage VBAT from the battery voltage VBAT supplied from the battery power source. The LDO circuit 122 may generate the positive voltage VLDO having a level corresponding to the reference voltage VBGR generated in the BGR circuit 121 using the battery voltage VBAT.

The voltage VLDO generated by the LDO circuit 122 may be provided to the clock generator 123 and clock generator 124.

The clock generator 123 and the charge pump circuit 125 may be used to generate a gate control voltage for controlling the transistor SW1.

The clock generator 124 and charge pump circuit 126 may be used to generate a gate control voltage to control transistor SW2.

The clock generator 123 may operate based on an enable signal EN_CP1, and output a clock signal CLK1 and an inverted clock signal CLK1′ having a voltage VLDO and a ground voltage according to the signal V_OSC input from the oscillator. The inverted clock signal CLK1′ may be a signal obtained by inverting the clock signal CLK1.

The clock generator 124 may operate based on an enable signal EN_CP2, and output a clock signal CLK2 and an inverted clock signal CLK2′ having a voltage VLDO and a ground voltage according to the signal V_OSC input from the oscillator. The inverted clock signal CLK2′ may be a signal obtained by inverting the clock signal CLK2.

According to an embodiment, the logic signal VLOG1 of the logic circuit 111, shown in FIG. 3, may be used as the enable signal EN_CP1. The logic signal VLOG2 of the logic circuit 111, shown in FIG. 3, may be used as an enable signal EN_CP2. As shown in FIG. 9, in the period TD2, the logic signal VLOG1 is at a high level, so the clock generator 123 may operate. In this case, the logic signal VLOG2 is at a low level, so the clock generator 124 may not be operated. Meanwhile, in the period TD3, the logic signal VLOG2 is at a high level, so the clock generator 124 may operate, and the logic signal VLOG1 is at a low level, so the clock generator 124 may not be operated.

The charge pump circuit 125 may generate a positive voltage V_OUT_CP1 higher than the power supply voltage VCC1 by charge pumping the power supply voltage VCC1 according to the clock signal CLK1 and the inverted clock signal CLK1′, and provide the positive voltage V_OUT_CP1 to the buffer control circuit 130.

The charge pump circuit 126 may generate a positive voltage V_OUT_CP2 higher than the power supply voltage VCC2 by charge pumping the power supply voltage VCC2 according to the clock signal CLK2 and the inverted clock signal CLK2′, and provide the positive voltage V_OUT_CP2 to the buffer control circuit 140.

The buffer control circuit 130 may provide an on-control voltage corresponding to the on-control signal to the gate of the transistor SW1 based on the control signal SW1_CONT. The buffer control circuit 130 may provide an off-control voltage corresponding to the off-control signal to the gate of the transistor SW1 based on the control signal SW1_CONT. Here, the on-control voltage may be the positive voltage V_OUT_CP1, and the off-control voltage may be a ground voltage. Alternatively, the off-control voltage may be a negative voltage.

The buffer control circuit 140 may provide an on-control voltage corresponding to the on-control signal to the gate of the transistor SW2 based on the control signal SW2_CONT. The buffer control circuit 130 may provide an off-control voltage corresponding to the off-control signal to the gate of the transistor SW2 based on the control signal SW2_CONT. Here, the on-control voltage may be the positive voltage V_OUT_CP2, and the off-control voltage may be a ground voltage. Alternatively, the off-control voltage may be a negative voltage.

When the off-control voltage is a negative voltage, a negative voltage may be generated from the voltage VLDO generated by the LDO circuit 122 using an additional charge pump circuit.

According to the embodiment, the delay signal VEDL1 of the first delay circuit 112, shown in FIG. 3, may be used as the control signal SW1_CONT. The delay signal VEDL2 of the second delay circuit 113 shown in FIG. 3 may be used as the control signal SW2_CONT. Accordingly, the buffer control circuit 130 may turn on the transistor SW1 after a predetermined delay time Δt when the logic signal VLOG1 changes from the low level to the high level, and the buffer control circuit 140 may turn on the transistor SW2 after a predetermined delay time Δt when the logic signal VLOG2 changes from the low level to the high level. As a result, it is possible to prevent the transistor SW1 and transistor SW2 from turning on at the same time.

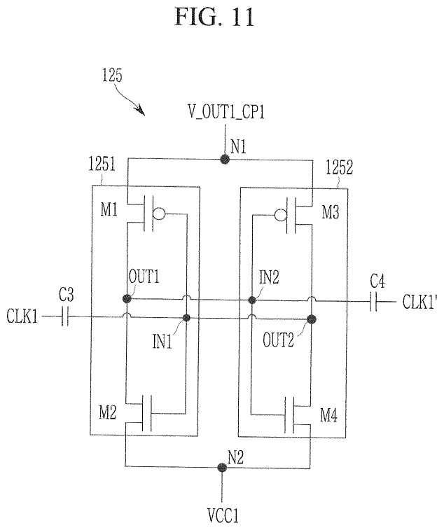

FIG. 11 is a diagram illustrating an example of the charge pump circuit 125 shown in FIG. 10.

Referring to FIG. 11, the charge pump circuit 125 may include a pumping capacitor C3, a pumping capacitor C4, an inverter 1251, and an inverter 1252.

The clock signal CLK1 may be input to one end of the pumping capacitor C3, and the other end of the pumping capacitor C3 may be connected to an input terminal IN1 of the inverter 1251. Furthermore, the other end of the pumping capacitor C3 may be connected to an output terminal OUT2 of the inverter 1252.

The inverted clock signal CLK1′ may be input to one end of the pumping capacitor C4, and the other end of the pumping capacitor C4 may be connected to an input terminal IN2 of the inverter 1252. Furthermore, the other end of the pumping capacitor C4 may be connected to an output terminal OUT1 of the inverter 1251.

The inverter 1251 may include a p-type transistor M1 and an n-type transistor M2. A source of the p-type transistor M1 is a power supply terminal, and may be connected to a node N1, and a source of the n-type transistor M2 is a power terminal, and may be connected to a node N2. A drain of the p-type transistor M1 and a drain of the n-type transistor M2 may be the output terminal OUT1 of the inverter 1251, and a gate of the p-type transistor M1 and a gate of the n-type transistor M2 may be an input terminal IN1 of the inverter 1251.

The inverter 1252 may include a p-type transistor M3 and an n-type transistor M4. A source of the p-type transistor M3 is a power supply terminal, and may be connected to the node N1, and a source of the n-type transistor M4 is a power supply terminal, and may be connected to the node N2. A drain of the p-type transistor M3 and a drain of the n-type transistor M4 may be an output terminal OUT2 of the inverter 1252, and a gate of the p-type transistor M3 and a gate of the n-type transistor M4 may be an input terminal IN2 of the inverter 1252.

This charge pump circuit 125 may generate an output voltage V_OUT_CP1 from an input voltage in which the voltage VLDO and the ground voltage are repeated according to the clock signal CLK1 and the inverted clock signal CLK1′.

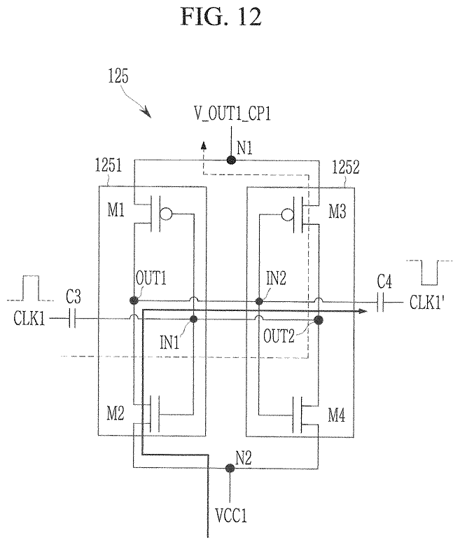

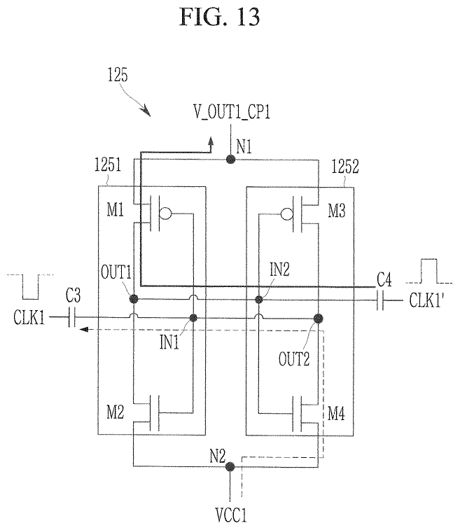

Then, a method of generating the output voltage V_OUT_CP1 in the charge pump circuit 125 will be described with reference to FIGS. 12 and 13.

FIG. 12 is a diagram showing the operating state of the charge pump circuit 125 in the first operation section, and FIG. 13 is a diagram showing the operating state of the charge pump circuit 125 in the second operation section.

Referring to FIG. 12, the clock signal CLK1 and the inverted clock signal CLK1′ may have the VLDO voltage as a high level and 0V as a low level.

In a first operation period, the clock signal CLK1 may have a high level and the inverted clock signal CLK1′ may have a low level. The voltage VLDO may be applied to the pumping capacitor C3 by the clock signal CLK1 having the high level, and 0V may be output to the pumping capacitor C4 by the inverted clock signal CLK1′ having the low level. Accordingly, the n-type transistor M2 of the inverter 1251 may be turned on, so the inverter 1251 may output the voltage VCC1 through the output terminal OUT1 of the inverter 1251, the pumping capacitor C4 may be charged with the VCC1 voltage, and the pumping capacitor C3 may be charged with the voltage VLDO. Furthermore, the p-type transistor M3 of the inverter 1252 may be turned on, and the voltage VLDO charged in the pumping capacitor C3 may be transmitted to the node N1 through the output terminal OUT2 of the inverter 1252 and p-type transistor M3 of the inverter 1252.

Next, referring to FIG. 13, in a second operation period, the clock signal CLK1 may have a low level and the inverted clock signal CLK1′ may have a high level. In the first operation section, the pumping capacitor C3 is charged with the VLDO voltage, and the pumping capacitor C4 is charged with the voltage VCC1. In the second operation period, 0V is applied to the pumping capacitor C3 by the clock signal CLK1 having the 0V, and the voltage VLDO is applied to the pumping capacitor C4 by the inverted clock signal CLK1′ having the high level. Accordingly, the voltage VLDO+VCC1 may be charged in the pumping capacitor (C4), the p-type transistor M1 of the inverter 1251 may be turned on, and the voltage VLDO+VCC1 charged in the pumping capacitor C4 may be transmitted to the node N1 through the output terminal OUT1 of the inverter 1251 and p-type transistor M1 of inverter 1251. Furthermore, the n-type transistor M4 of the inverter 1252 may be turned on, so the inverter 1252 may output the voltage VCC1 through the output terminal OUT2 by the n-type transistor M4, and the pumping capacitor C3 may be charged with the voltage VLDO+VCC1.

According to the clock signal CLK1 and the inverted clock signal CLK1′, the first operation period shown in FIG. 12 and the second operation period shown in FIG. 13 may be repeated, and the voltage of the node N1 may gradually increase and eventually become the voltage VLDO+VCC1. That is, the charge pump circuit 125 may output a positive voltage VLDO+VCC1 as the output voltage V_OUT_CP1.

In this way, the charge pump circuit 125 may provide a voltage VLDO+VCC1 higher than the voltage VCC1 as the on-control signal of the transistor SW1.

The charge pump circuit 126 may also be configured similarly or identically to the charge pump circuit 125. The charge pump circuit 126 may provide a voltage VLDO+VCC1 higher than the voltage VCC1 as the on-control signal of the transistor SW2.

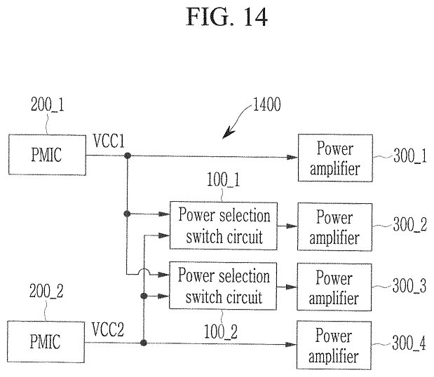

FIG. 14 is a diagram illustrating an example of a communication terminal system to which the power selection switch circuit shown in FIG. 1 is applied.

Referring to FIG. 14, the communication terminal system 1400 may include a plurality of power amplifiers 300_1, 300_2, 300_3, and 300_4, power selection switch circuits 100_1 and 100_2, and PMICs 200_1 and 200_2.

The power amplifier 300_1 may operate by receiving a power supply voltage VCC1 from the PMIC 200_1, amplify an input RF signal, and output the amplified RF signal.

The power amplifier 300_4 may operate by receiving a power supply voltage VCC2 from the PMIC 200_2, amplify an input RF signal, and output the amplified RF signal.

The power amplifier 300_2 may operate by receiving a power supply voltage selected by the power selection switch circuit 100_1, and amplify an input RF signal and output the amplified RF signal.

The power amplifier 300_3 may operate by receiving the power voltage selected by the power selection switch circuit 100_2, amplify the input RF signal, and output the amplified RF signal.

The power selection switch circuit 100_1 may select one of the power supply voltages VCC1 and VCC2 and provide the selected power supply voltage to the power amplifier 300_2.

The power selection switch circuit 100_2 may select one of the power supply voltages VCC1 and VCC2 and provide the selected power supply voltage to the power amplifier 300_3.

The PMIC 200_1 may generate the power supply voltage VCC1 from the main power supply.

The PMIC 200_2 may generate the power supply voltage VCC2 from the main power supply.

Generally, four PMICs are desired to operate four power amplifiers, but by using the power selection switch circuit, the number of PMICs may be reduced, and the cost of the communication terminal system may be lowered.

Additionally, as described above, in the power selection switch circuits 100_1 and 100_2, respectively, two transistors SW1 and SW2 may be configured as n-type transistors, thereby reducing the size of a power amplifier module when implementing the power amplifier module.

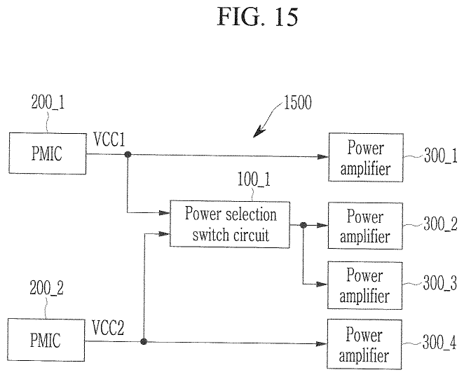

FIG. 15 is a diagram showing another example of a communication terminal system to which the power selection switch circuit shown in FIG. 1 is applied.

Referring to FIG. 15, unlike FIG. 12, the power amplifier 300_3 of the communication terminal system 1500 may receive a power supply voltage from the power selection switch circuit 100_1.

In this way, the number of power selection switches may be reduced compared to FIG. 12.

According to at least one of the embodiments, the number of power ICs can be reduced by selectively providing a power supply voltage to the power amplifier through a power selection switch circuit.

According to at least one of the embodiments, it is possible to prevent two transistors in the power selection switch circuit from turning on at the same time, thereby protecting the power amplifier from overcurrent.

According to at least one of the embodiments, two transistors in the power selection switch circuit are configured as n-type transistors, so that the mounting area of the two transistors in the power amplifier module may be reduced compared to the case where each transistor in the power selection switch circuit is configured with a p-type transistor and an n-type transistor.

At least one of the embodiments may provide a power selection switch circuit that may reduce the size of a power amplifier module.

At least one of the embodiments may provide a power selection switch circuit capable of providing a gate control voltage at a voltage level sufficiently higher than the input DC power voltage.

While specific examples have been shown and described above, it will be apparent after an understanding of this disclosure that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A power selection switch circuit configured to select either one or both of a first power supply voltage and a second power supply voltage, and supply the selected power supply voltage to a power amplifier, the power selection switch circuit comprising:
an n-type first transistor configured to turn on in response to a first switching control signal having a first voltage generated by charge pumping the first power supply voltage, and supply the first power supply voltage to a power supply terminal of the power amplifier when turned on; and
an n-type second transistor configured to turn on in response to a second switching control signal having a second voltage generated by charge pumping the second power supply voltage, and supply the second power supply voltage to the power supply terminal of the power amplifier when turned on.

2. The power selection switch circuit of claim 1, further comprising:
a switching controller configured to generate the first switching control signal and the second switching control signal using a first bit signal and a second bit signal externally input so that a transistor that is turned on from a turn-off state, among the n-type first transistor and the n-type second transistor, is turned on after being delayed by a predetermined time, and a transistor that is turned off from a turn-on state, among the n-type first transistor and the n-type second transistor, is turned off immediately,
wherein the n-type first transistor is configured to turn off in response to the first switching control signal having a third voltage lower than the first voltage, and the second transistor is configured to turn off in response to the second switching control signal having a fourth voltage lower than the second voltage.

3. The power selection switch circuit of claim 2, wherein the switching controller comprises:
a logic circuit configured to generate a first logic signal for generating the first switching control signal and a second logic signal for generating the second switching control signal by combining the first bit signal and the second bit signal;
a first delay circuit configured to delay the first logic signal to generate a first delay signal;
a second delay circuit configured to delay the second logic signal to generate a second delay signal;
a first buffer control circuit configured to supply the first voltage or the third voltage as the first switching control signal to a control terminal of the n-type first transistor in response to the first delay signal; and
a second buffer control circuit configured to supply the second voltage or the fourth voltage as the second switching control signal to a control terminal of the n-type second transistor in response to the second delay signal.

4. The power selection switch circuit of claim 3, wherein
the first bit signal and the second bit signal have a value of 0 or 1, and
the logic circuit is configured to set both the first logic signal and the second logic signal to a low level so that when the first bit signal and the second bit signal are both 1 or both 0, both the n-type first transistor and the n-type second transistor are turned off.

5. The power selection switch circuit of claim 4, wherein the switching controller further comprises:
a first clock generator configured to operate in response to the first logic signal, and generate a first clock signal having a fifth voltage and a sixth voltage lower than the fifth voltage;
a second clock generator configured to operate in response to the second logic signal, and generate a second clock signal having the fifth voltage and the sixth voltage;
a first charge pump circuit configured to generate the first voltage by charge pimping the first power supply voltage by the fifth voltage in response to the first clock signal, and provide the first voltage to the first buffer control circuit; and
a second charge pump circuit configured to generate the second voltage by charge pimping the second power supply voltage by the fifth voltage in response to the second clock signal, and provide the second voltage to the second buffer control circuit.

6. The power selection switch circuit of claim 5, wherein
the first logic signal and the second logic signal have a high level and a low level, and
the first clock generator and the second clock generator operate at the high level of the first logic signal and the high level of the second logic signal, and do not operate at the low level.

7. The power selection switch circuit of claim 4, wherein the logic circuit comprises:
a NAND gate configured to receive the first bit signal and the second bit signal;
a first AND gate configured to receive the first bit signal and an output of the NAND gate, and output the first logic signal; and
a second AND gate configured to receive the second bit signal and an output of the NAND gate, and output the second logic signal.

8. The power selection switch circuit of claim 3, wherein the first delay circuit comprises:
a first delay cell configured to delay the first logic signal; and
a first AND gate configured to receive the first logic signal and a signal delayed by the first delay cell, and
wherein the second delay circuit comprises:
a second delay cell configured to delay the second logic signal; and
a second AND gate configured to receive the second logic signal and a signal delayed by the second delay cell.

9. A power amplifier module, comprising:
the power amplifier and the power selection switch circuit of claim 1.

10. A power amplifier module comprising:
a power amplifier configured to receive a power supply voltage from a power supply terminal, and amplify an input signal and output the amplified signal; and
a power selection switch circuit configured to provide either one or both power supply voltage of a first power supply voltage, supplied from a first power integrated circuit (IC), and a second power supply voltage, supplied from a second power IC to the power supply terminal, wherein
the power selection switch circuit comprises:
an n-type first transistor configured to have a first terminal connected to the first power IC, a second terminal connected to the power supply terminal, and a control terminal receiving a first switching control signal having a first voltage generated by charge pumping the first power supply voltage; and
an n-type second transistor configured to have a first terminal connected to the second power IC, a second terminal connected to the power supply terminal, and a control terminal receiving a second switching control signal having a second voltage generated by charge pumping the second power supply voltage.

11. The power amplifier module of claim 10, wherein the power selection switch circuit further comprises
a switching controller configured to generate the first switching control signal and the second switching control signal so that the n-type first transistor and the n-type second transistor are turned on after being delayed by a predetermined time when the n-type first transistor and the n-type second transistor change from the turn-off state to the turn-on state.

12. The power amplifier module of claim 11, wherein
the n-type first transistor is configured to turn off in response to the first switching control signal having a third voltage lower than the first voltage, and the n-type second transistor is configured to turn off in response to the second switching control signal having a fourth voltage lower than the second voltage.

13. The power amplifier module of claim 12, wherein the switching controller comprises:
a logic circuit configured to generate a first logic signal for generating the first switching control signal and a second logic signal for generating the second switching control signal by combining a first bit signal and a second bit signal input from an outside;
a first delay circuit configured to delay the first logic signal to generate a first delay signal;
a second delay circuit configured to delay the second logic signal to generate a second delay signal;
a first buffer control circuit configured to supply the first voltage or the third voltage as the first switching control signal to a control terminal of the n-type first transistor in response to the first delay signal; and
a second buffer control circuit configured to supply the second voltage or the fourth voltage as the second switching control signal to a control terminal of the n-type second transistor in response to the second delay signal.

14. The power amplifier module of claim 13, wherein
the first bit signal and the second bit signal have a value of 0 or 1, and
the logic circuit is configured to set both the first logic signal and the second logic signal to a low level so that when the first bit signal and the second bit signal are both 1 or both 0, both the n-type first transistor and the n-type second transistor are turned off.

15. The power amplifier module of claim 14, wherein the switching controller comprises:
a first clock generator configured to operate in response to the first logic signal and generate a first clock signal having a fifth voltage and a sixth voltage lower than the fifth voltage;
a second clock generator configured to operate in response to the second logic signal and generate a second clock signal having the fifth voltage and the sixth voltage;
a first charge pump circuit configured to generate the first voltage by charge pimping the first power supply voltage by the fifth voltage in response to the first clock signal, and provide the first voltage to the first buffer control circuit; and
a second charge pump circuit configured to generate the second voltage by charge pimping the second power supply voltage by the fifth voltage in response to the second clock signal, and provide the second voltage to the second buffer control circuit.

16. The power amplifier module of claim 10, wherein
the n-type first transistor comprises a plurality of third transistors connected in parallel,
the n-type second transistor comprises a plurality of fourth transistors connected in parallel, and
the plurality of third transistor and the plurality of fourth transistor are n-type transistors.
